(19) United States
(12) Patent Application Publication
(10) Pub. No.: US 2026/0150423 A1
(43) Pub. Date: May 28, 2026

(54) PHOTOELECTRIC CONVERSION DEVICE, PHOTOELECTRIC CONVERSION SYSTEM, MOVING BODY, APPARATUS, AND MANUFACTURING METHOD OF PHOTOELECTRIC CONVERSION DEVICE

(71) Applicant: CANON KABUSHIKI KAISHA, Tokyo (JP)

(72) Inventors: KOSUKE ASANO, Kanagawa (JP); TETSUYA KIMURA, Tokyo (JP)

(21) Appl. No.: 19/389,893

(22) Filed: Nov. 14, 2025

(30) Foreign Application Priority Data
Nov. 26, 2024 (JP) 2024-205698

(51) Int. Cl. H10F 39/00; H10F 39/18

(52) U.S. Cl. CPC H10F 39/807; H10F 39/014; H10F 39/182; H10F 39/8063

(57) ABSTRACT

A photoelectric conversion device including: a semiconductor layer having a first main surface and a second main surface and including a first photoelectric conversion element and a second photoelectric conversion element adjacent to each other; and an element isolation portion arranged to electrically isolate the first photoelectric conversion element and the second photoelectric conversion element, is provided. A cured product of a curable composition is arranged on the first main surface, a plurality of trenches extending from a surface of the cured product toward the first main surface are provided in the cured product, and the plurality of trenches include a first trench constituting a scattering diffraction structure arranged to overlap the first photoelectric conversion element, and a second trench constituting an isolation structure arranged to overlap the element isolation portion.

### BACKGROUND

### Field of the Technology

The present disclosure relates to a photoelectric conversion device, a photoelectric conversion system, a moving body, an apparatus, and a manufacturing method of the photoelectric conversion device.

### Description of the Related Art

Japanese Patent Laid-Open No. 2018-093234 discusses a solid-state image capturing device where a fine concave-convex structure is provided in the light receiving surface of a semiconductor substrate to refract incident light, thereby increasing the optical path length that the incident light travels through a photoelectric conversion region and improving photoelectric conversion efficiency. Japanese Patent Laid-Open No. 2018-093234 also discusses used of dry etching to form the concave-convex structure.

The dry etching for forming the concave-convex structure in the semiconductor substrate may cause plasma damage to the semiconductor substrate. Due to this, dark current noise or the like is generated, and characteristics can be degraded.

### SUMMARY

Embodiments of the present disclosure provide a technique for improving the characteristics of a photoelectric conversion device.

An aspect of the present disclosure provides a photoelectric conversion device that includes a semiconductor layer having a first surface, a first photoelectric conversion element, and a second photoelectric conversion element adjacent to each other; and an isolation portion arranged to electrically isolate the first photoelectric conversion element from the second photoelectric conversion element. The first surface is configured for a cured product to be arranged thereon. A plurality of trenches extending from a surface of the cured product toward the first surface are provided in the cured product. A first trench of the plurality of trenches forms a scattering diffraction structure arranged to overlap the first photoelectric conversion element. A second trench of the plurality of trenches forms an isolation structure arranged to overlap the isolation portion.

Features of the present disclosure will become apparent from the following description of embodiments with reference to the attached drawings. The following description of embodiments is provided by way of example.

### BRIEF DESCRIPTION OF THE DRAWINGS

FIG. 1 is a view showing an arrangement example of a photoelectric conversion device according to an embodiment;

FIG. 2 is a view showing an arrangement example of the pixel array of the photoelectric conversion device shown in FIG. 1;

FIG. 3 is a block diagram showing an arrangement example of the photoelectric conversion device shown in FIG. 1;

FIG. 4 is a circuit diagram showing an example arrangement of the pixel of the photoelectric conversion device shown in FIG. 1;

FIGS. 5A and 5B are views for explaining an operation example of the pixel of the photoelectric conversion device shown in FIG. 1;

FIG. 6 is a sectional view showing an arrangement example of the pixels of the photoelectric conversion device shown in FIG. 1;

FIGS. 7A and 7B are plan views showing an arrangement example of the pixels shown in FIG. 6;

FIG. 8 is a sectional view showing an example of a manufacturing step of the pixels shown in FIG. 6;

FIG. 9 is a sectional view showing an example of a manufacturing step of the pixels shown in FIG. 6;

FIG. 10 is a sectional view showing an example of a manufacturing step of the pixels shown in FIG. 6;

FIG. 11 is a sectional view showing an example of a manufacturing step of the pixels shown in FIG. 6;

FIG. 12 is a sectional view showing an example of a manufacturing step of the pixels shown in FIG. 6;

FIG. 13 is a sectional view showing a modification of the pixels shown in FIG. 6;

FIG. 14 is a sectional view showing a modification of the pixels shown in FIG. 6;

FIG. 15 is a sectional view showing a modification of the pixels shown in FIG. 6;

FIG. 16 is a functional block diagram of a photoelectric conversion system using the photoelectric conversion device according to an embodiment;

FIGS. 17A and 17B are functional block diagrams of a photoelectric conversion system using the photoelectric conversion device according to an embodiment;

FIG. 18 is a functional block diagram of a photoelectric conversion system using the photoelectric conversion device according to an embodiment;

FIG. 19 is a functional block diagram of a photoelectric conversion system using the photoelectric conversion device according to an embodiment;

FIGS. 20A and 20B are views each showing a photoelectric conversion system using the photoelectric conversion device according to an embodiment; and

FIG. 21 is a view showing an arrangement example of an imprint apparatus that is used to manufacture the photoelectric conversion device according to an embodiment.

### DESCRIPTION OF THE EMBODIMENTS

Hereinafter, embodiments will be described in detail with reference to the attached drawings. The following embodiments are not intended to limit the scope of the claims. Multiple features are described in the embodiments, but it is not the case that all such features are required, and multiple such features may be combined as appropriate. In the attached drawings, the same reference numerals are given to the same or similar configurations, and redundant description thereof is omitted.

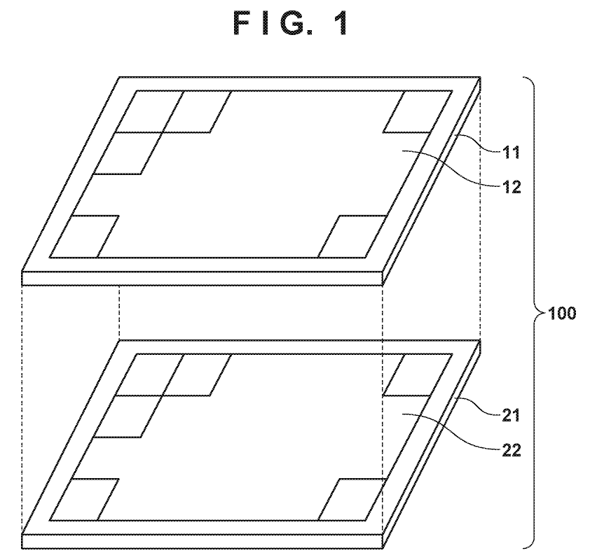

With reference to FIGS. 1-5, an avalanche photodiode (APD) 201 can be used as a photoelectric conversion element in a photoelectric conversion device 100, as described below. The photoelectric conversion element is not limited to the APD, and another type of photodiode such as a PN diode or a PIN diode may be used as the photoelectric conversion element in the photoelectric conversion device 100.

FIG. 1 is a view showing an arrangement example of the photoelectric conversion device 100. The photoelectric conversion device 100 can be constituted by stacking two boards, that is, a sensor board 11 (to be sometimes simply referred to as a board 11 hereinafter) and a circuit board 21 and electrically connecting them. That is, the photoelectric conversion device 100 may be a stacked device. In the board 11, a semiconductor layer 301 in which a plurality of pixels 101a…101n are arranged, and the like are arranged, which will be described later, with a pixel of the plurality of pixels referred to as pixel 101. A pixel region 12 including the plurality of pixels 101 is arranged in the board 11. A circuit region 22 where a signal detected in the pixel region 12 is processed is arranged in the circuit board 21.

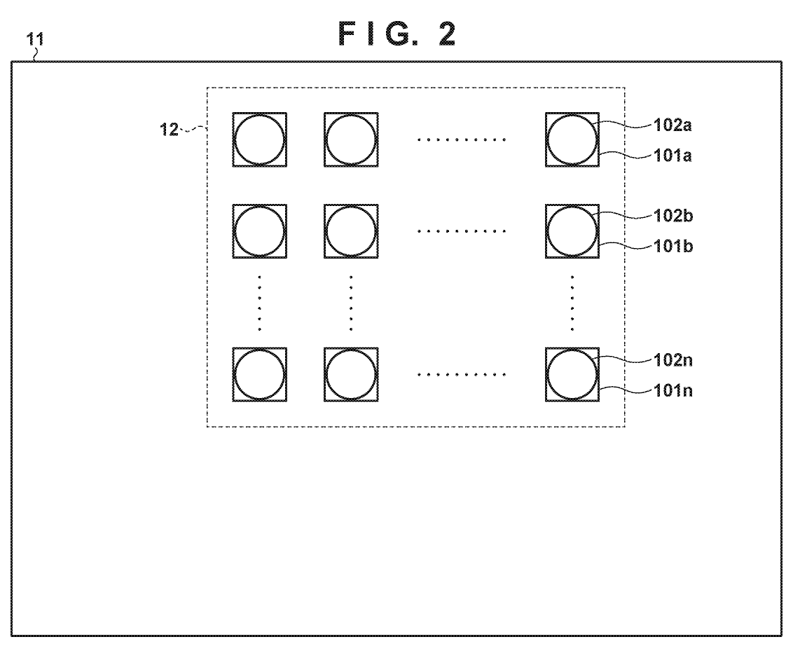

FIG. 2 is a view showing an arrangement example of the board 11. Each pixel of the plurality of pixels 101 has a respective photoelectric conversion element 102a…102n, with a photoelectric conversion element of the plurality of photoelectric conversion elements 102a…102n referred to as photoelectric conversion element 102, that includes an APD 201 as a photodiode. The plurality of pixels 101 are arranged in a two-dimensional array in an orthogonal projection to a main surface 391 (first surface) of the board 11, forming the pixel region 12. The pixel 101 is typically configured to generate an image. When used in a Time of Flight (ToF) distance measurement device, the pixel 101 may not always generate an image. That is, the pixel 101 may be configured to measure the time when light arrives and the quantity of light.

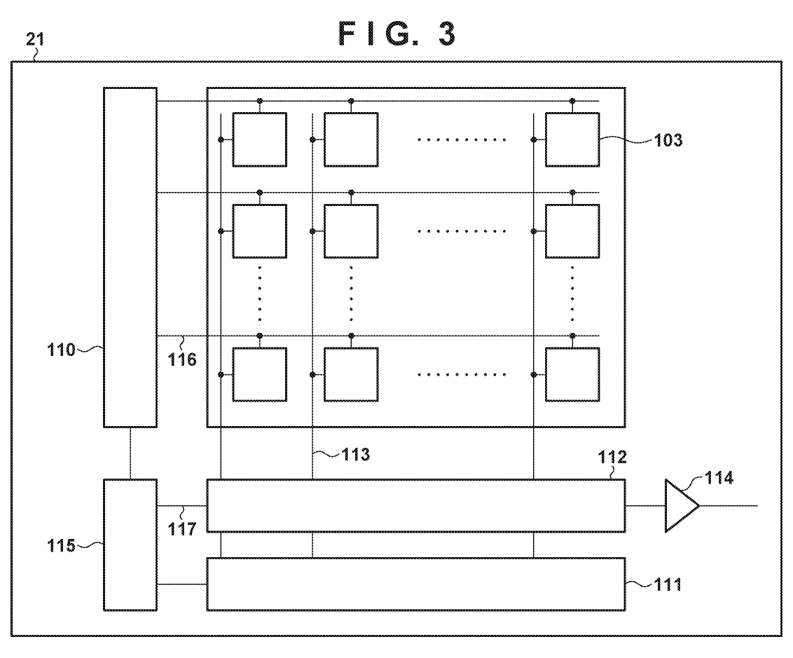

FIG. 3 is a block diagram showing an arrangement example of the circuit board 21. The circuit board 21 includes signal processing circuits 103 that process charges photoelectrically converted by the photoelectric conversion elements 102 shown in FIG. 2, a readout circuit 112, a control pulse generation circuit 115, a horizontal scanning circuit 111, signal lines 113, a vertical scanning circuit 110, and the like. The signal processing circuits 103 shown in FIG. 3 may be arranged so as to correspond to each pixel 101 shown in FIG. 2. In this case, the pixel 101 (photoelectric conversion element 102) and the signal processing circuit 103 may be electrically connected via a connection wiring provided for each pixel 101.

The vertical scanning circuit 110 receives a control pulse supplied from the control pulse generation circuit 115, and supplies a control pulse to the respective pixels 101 via driving lines 116. A logic circuit such as a shift register or an address decoder can be used for the vertical scanning circuit 110.

A signal output from the pixel 101 is processed by the signal processing circuit 103. A counter, a memory, and the like can be provided in the signal processing circuit 103. The memory can hold, as a digital value, a count value obtained from the counter.

The horizontal scanning circuit 111 inputs, to the signal processing circuits 103, a control pulse for sequentially selecting respective columns in order to read out signals from the memories of the signal processing circuits 103 corresponding to the respective pixels 101 in which digital signals are held. As for a selected column, a signal is output to a signal line of the signal lines 113 from the signal processing circuit 103 corresponding to the pixel 101 selected by the vertical scanning circuit 110. The signal output to the signal line of the signal lines 113 is output via an output circuit 114 to a recording unit or a signal processing unit external to the photoelectric conversion device 100.

The array of the pixels 101 in the pixel region 12 shown in FIG. 2 is not limited to a two-dimensional array. For example, the pixels 101 may be arranged one-dimensionally. The function of the signal processing circuit 103 need not be provided for each of the pixels 101 (photoelectric conversion elements 102). For example, one signal processing circuit 103 may be shared between two or more pixels 101 (photoelectric conversion elements 102) to sequentially perform signal processing.

As shown in FIGS. 2 and 3, the signal processing circuits 103 can be arranged in a region overlapping the pixel region 12 in an orthogonal projection to the pixel region 12. The vertical scanning circuit 110, the horizontal scanning circuit 111, the readout circuit 112, the output circuit 114, the control pulse generation circuit 115, and the like can be arranged to overlap a gap between an end of the board 11 and an end of the pixel region 12. In other words, the board 11 has the pixel region 12 and a non-pixel region (peripheral region) arranged around the pixel region 12. In this case, the vertical scanning circuit 110, the horizontal scanning circuit 111, the readout circuit 112, the output circuit 114, and the control pulse generation circuit 115 can be arranged in a region overlapping the non-pixel region.

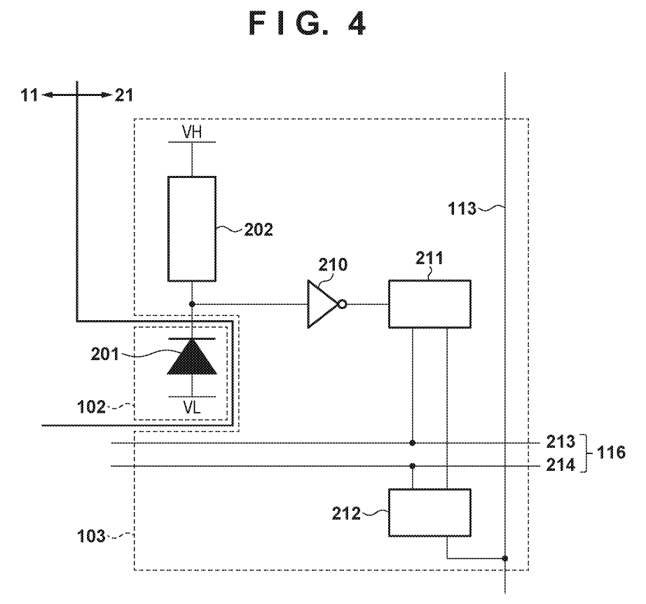

FIG. 4 is a block diagram including an equivalent circuit focusing on one photoelectric conversion element 102. In FIG. 4, the photoelectric conversion element 102 including an APD 201 is provided in the board 11, and the remaining components are provided in the circuit board 21.

The APD 201 generates a charge pair corresponding to incident light by photoelectric conversion. A potential VL is supplied to the anode of the APD 201. A potential VH higher than the potential VL supplied to the anode is supplied to the cathode of the APD 201. A reverse bias voltage is supplied to the anode and the cathode so that the APD 201 performs an avalanche breakdown operation. In a state in which such a reverse bias voltage is supplied, charges generated by incident light cause avalanche breakdown, generating an avalanche current.

In a case where the reverse bias voltage is supplied to the APD 201, there are a Geiger mode in which the APD 201 is operated by a potential difference (voltage) between the anode and the cathode larger than a breakdown voltage, and a linear mode in which the APD 201 is operated by a potential difference between the anode and the cathode around the breakdown voltage or equal to or lower than the breakdown voltage. An APD operated in the Geiger mode is called a Single Photon Avalanche Diode (SPAD). For example, the potential VL is -30 V, and the potential VH is 1 V. The APD 201 may be operated in the linear mode or the Geiger mode.

A quench element 202 is connected between a power supply that supplies the potential VH, and the APD 201. The quench element 202 functions as a load circuit (quench circuit) at the time of signal multiplication by avalanche breakdown, and operates to suppress a voltage supplied to the APD 201 and suppress avalanche breakdown (quench operation). The quench element 202 also operates to return the voltage supplied to the APD 201 to a voltage (VH - VL) by supplying a current by an amount corresponding to a voltage drop caused by the quench operation (recharge operation).

The signal processing circuit 103 can include a waveform shaping circuit 210, a counter circuit 211, and a selection circuit 212. Herein, the signal processing circuit 103 may include any of the waveform shaping circuit 210, the counter circuit 211, and the selection circuit 212.

The waveform shaping circuit 210 shapes a potential change of the cathode of the APD 201 that is obtained at the time of photon detection, and outputs a pulse signal. As the waveform shaping circuit 210, for example, an inverter circuit is used. In the arrangement shown in FIG. 4, the use of one inverter as the waveform shaping circuit 210 is exemplified. However, the present disclosure is not so limited, and a circuit constituted by series-connecting a plurality of inverters may be used as the waveform shaping circuit 210 or another circuit having the waveform shaping effect may be used.

The counter circuit 211 counts pulse signals output from the waveform shaping circuit 210 and holds the count value. When a control pulse pRES is supplied from the vertical scanning circuit 110 shown in FIG. 3 via a driving line 213 corresponding to a part of the driving line 116 shown in FIG. 3, the signal held by the counter circuit 211 is reset.

The selection circuit 212 receives a control pulse pSEL from the vertical scanning circuit 110 via a driving line 214 corresponding to a part of the driving line 116 shown in FIG. 3, and switches electrical connection or disconnection between the counter circuit 211 and the signal line 113. The selection circuit 212 can include, for example, a buffer circuit for outputting a signal.

A switching element such as a transistor may be interposed between the quench element 202 and the APD 201 or between the photoelectric conversion element 102 and the signal processing circuit 103 so that electrical connection can be switched. Similarly, supply of the potential VH or potential VL to the photoelectric conversion element 102 may be electrically switchable using a switching element such as a transistor.

In this embodiment, the counter circuit 211 is arranged in the signal processing circuit 103. However, the present disclosure is not so limited, and a Time-to-Digital Converter (TDC) and a memory may be used instead of the counter circuit 211 so that the photoelectric conversion device 100 obtains a pulse detection timing. In this case, the generation timing of a pulse signal output from the waveform shaping circuit 210 is converted into a digital signal by the TDC. The TDC receives a control pulse pREF (reference signal) from the vertical scanning circuit 110 via the driving line 116 for measurement of the timing of the pulse signal. By using the control pulse pREF as a reference, the TDC obtains, as a digital signal, a signal when the input timing of a signal output from each pixel 101 via the waveform shaping circuit 210 is regarded as a relative time.

In the arrangement shown in FIG. 4, the quench element 202, the waveform shaping circuit 210, the counter circuit 211, and the selection circuit 212 are arranged in one circuit board 21. However, the present disclosure is not so limited. For example, the quench element 202 and the waveform shaping circuit 210 may be arranged in one substrate, the counter circuit 211 and the selection circuit 212 may be arranged in another substrate, and these substrates may be stacked.

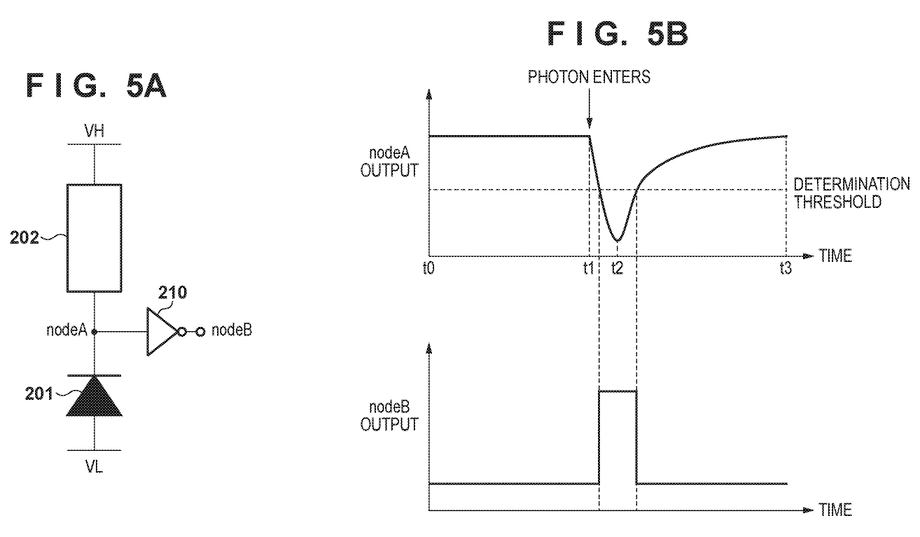

FIGS. 5A and 5B are views schematically showing the relationship between the operation of the APD 201 and an output signal. FIG. 5A is a view showing an excerpt of the APD 201, quench element 202, and waveform shaping circuit 210 shown in FIG. 4. Here, the input side of the waveform shaping circuit 210 is a node A and its output side is a node B. FIG. 5B shows waveform changes at the node A and the node B.

From time t0 to time t1, a potential difference (voltage) of the potential VH - the potential VL is applied to the APD 201. When a photon enters the APD 201 at time t1, avalanche breakdown occurs in the APD 201, an avalanche breakdown current flows into the quench element 202, and the potential of the node A drops. When the voltage drop amount further increases and the potential difference applied to the APD 201 decreases, the avalanche breakdown of the APD 201 stops as shown at time t2, and the potential level of the node A does not drop any more from a predetermined value. In a period between time t2 and time t3, a current compensating for the voltage drop from the potential VL flows to the node A. At time t3, the node A is settled at the original potential level. A portion at which the output waveform exceeds a given threshold at the node A is waveform-shaped by the waveform shaping circuit 210 and output as a signal to the node B.

The arrangement of the signal lines 113, readout circuit 112, and output circuit 114 is not limited to the arrangement shown in FIG. 3. For example, each signal line 113 may be arranged to extend in the row direction (the longitudinal direction in FIG. 3), and the readout circuit 112 may be arranged at the end of the signal line 113.

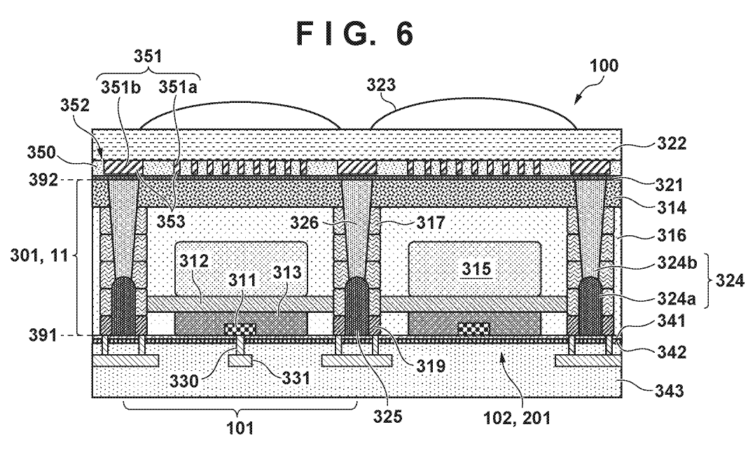

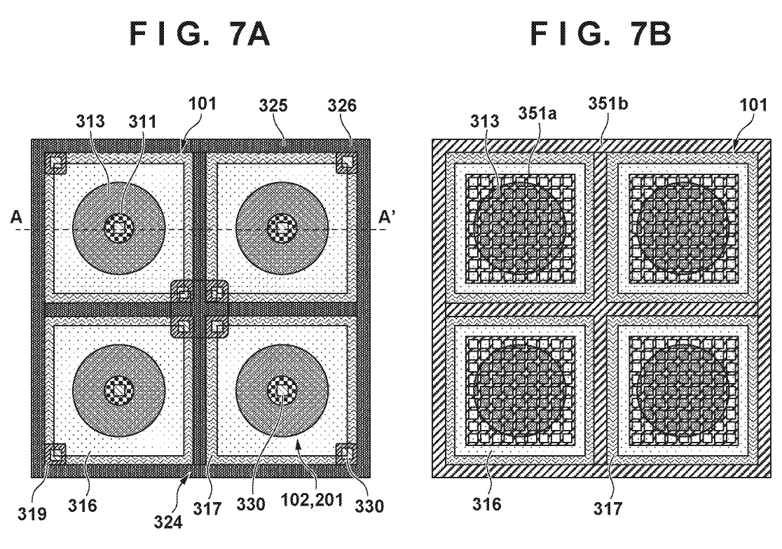

Next, the arrangement of the pixels 101 arranged in the photoelectric conversion device 100 according to this embodiment will be described in detail. FIG. 6 is a sectional view showing the arrangement of the pixels 101 arranged in the pixel region 12. FIGS. 7A and 7B are plan views showing the arrangement of the pixels 101. FIG. 6 is a sectional view taken along a line A - A' shown in FIG. 7A. FIG. 7A is a plan view at the main surface 391 of the semiconductor layer 301 shown in FIG. 6. FIG. 7B is a plan view focusing on trenches 351 provided in a cured product 350 of a curable composition arranged on the main surface 392 (second surface) of the semiconductor layer 301. The photoelectric conversion device 100 shown in FIGS. 6-7B has a back-illuminated type sensor configuration.

In the photoelectric conversion device 100, the plurality of pixels 101 are arranged in the board 11 formed of a semiconductor material. Each of the plurality of pixels 101 includes, as the above-described photoelectric conversion element 102, the APD 201 formed in the semiconductor layer 301 provided in the board 11. It can also be said that the semiconductor layer 301 having the main surface 391 and the main surface 392 includes the APD 201 as the photoelectric conversion element 102. Each pixel 101 (APD 201) is isolated by an element isolation portion 324 extending from the main surface 391 of the semiconductor layer 301 toward the main surface 392 and arranged to electrically isolate the adjacent APDs 201 from each other. Although not shown in FIG. 6, the photoelectric conversion device 100 further includes a semiconductor layer of the circuit board 21, which is different from the semiconductor layer 301 and arranged to face the main surface 391 of the semiconductor layer 301 (board 11) via an insulating layer 341, a protection layer 342, and an interlayer insulating layer 343. Elements such as transistors for operating the APD 201 as a photodiode can be arranged in the semiconductor layer of the circuit board 21. Here, an example will be described where the APD 201 is used as the photoelectric conversion element 102. However, as described above, each of the plurality of pixels 101 may use, as the photoelectric conversion element 102, another type of photodiode such as a PN diode or a PIN diode.

Each pixel 101 includes a semiconductor region 311, a semiconductor region 313, a semiconductor region 315, and a semiconductor region 316 of the same conductivity type. Each pixel 101 further includes a semiconductor region 312, a semiconductor region 314, a semiconductor region 317, and a semiconductor region 319 of a conductivity type opposite to the conductivity type of the semiconductor regions 311, 313, 315, and 316. For example, the semiconductor regions 311, 313, 315, and 316 may be n-type semiconductor regions, and the semiconductor regions 312, 314, 317, and 319 may be p-type semiconductor regions. An example of the semiconductor material used for the board 11 (semiconductor layer 301) is silicon. Accordingly, each of the semiconductor regions 311 to 317 and 319 can be a region obtained by doping an impurity corresponding to the conductivity type to silicon. For example, each of the semiconductor regions 311, 312, 313, 314, 315, 317, and 319 may be formed in the n-type semiconductor layer 301 (semiconductor region 316) using an ion implantation method or the like.

In the arrangement shown in FIG. 6, light enters from the upper side. That is, in the semiconductor layer 301, the main surface 392 is the light incident surface. The n-type semiconductor region 311 is arranged in the vicinity of the main surface 391 of the semiconductor layer 301, and the n-type semiconductor region 313 is arranged around the semiconductor region 311. The p-type semiconductor region 312 is arranged at a position where it overlaps the semiconductor region 311 and the semiconductor region 313 in the orthogonal projection to the main surface 391 of the semiconductor layer 301. Hereinafter, the expression "the semiconductor regions overlap" indicates that the semiconductor regions overlap in the orthogonal projection to the main surface 392 of the semiconductor layer 301. The expression "overlap" may also be used in other arrangements. The n-type semiconductor region 315 is further arranged at a position where it overlaps the semiconductor region 312, and the n-type semiconductor region 316 is arranged around the semiconductor region 315.

The semiconductor region 311 has a higher n-type impurity concentration than the semiconductor region 313 and the semiconductor region 315. A p-n junction portion is formed between the p-type semiconductor region 312 and the n-type semiconductor region 311. By setting the impurity concentration of the semiconductor region 312 lower than the impurity concentration of the semiconductor region 311, a reverse bias is applied and the whole region of the semiconductor region 312 overlapping the center of the semiconductor region 311 becomes a depletion layer region. In this case, the potential difference between the semiconductor region 311 and the semiconductor region 312 is larger than the potential difference between the semiconductor region 312 and the semiconductor region 315. Further, the depletion layer region extends to a partial region of the semiconductor region 311, and a strong electric field is induced in the depletion layer region. This strong electric field induces avalanche breakdown in the depletion layer region extending to the partial region of the semiconductor region 311, and a current based on the multiplied charges is output as a signal charge. When the light having entered the pixel 101 is photoelectrically converted and avalanche breakdown is induced in the depletion layer region (avalanche breakdown region), the generated n-type charges are collected in the semiconductor region 311.

The semiconductor region 311 is connected to a wiring pattern 331 via a contact plug 330. The semiconductor region 312 is connected to the wiring pattern 331 via the semiconductor regions 317 and 319 and the contact plug 330. By setting the impurity concentration of the semiconductor region 319 higher than the impurity concentration of the semiconductor region 317, the contact resistance between the semiconductor region 319 and the contact plug 330 is reduced. Here, the wiring pattern 331 connected to the semiconductor region 311 and the wiring pattern 331 connected to the semiconductor region 312 are different wiring patterns.

In FIG. 6, the semiconductor region 313 and the semiconductor region 315 are formed to have similar sizes in the plane direction, but the sizes of the respective semiconductor regions are not limited thereto. For example, the semiconductor region 315 may be formed larger than the semiconductor region 313 to collect charges to the semiconductor region 311 from a larger range. The semiconductor region 313 may be not an n-type semiconductor region but a p-type semiconductor region. In this case, the impurity concentration of the semiconductor region 313 is set lower than the impurity concentration of the semiconductor region 312. If the impurity concentration of the semiconductor region 313 is too high, an avalanche breakdown region is generated between the semiconductor region 313 and the semiconductor region 311, and the Dark Count Rate (DCR) may increase.

As described above, each pixel 101 (APD 201) is isolated by the element isolation portion 324. In the element isolation portion 324, insulators 325 and 326 are embedded. The insulators 325 and 326 may be fully embedded in the element isolation portion 324, or may have some voids. For each of the insulators 325 and 326, a material such as silicon oxide, silicon nitride, or silicon oxynitride may be used. Each of the insulators 325 and 326 may be formed from one material, or may have a multi-layered structure using multiple materials.

As shown in FIG. 6, the insulator 325 embedded in a part 324a of the element isolation portion 324 on the side of the main surface 391 of the semiconductor layer 301 may be added with particles of a metal oxide such as titanium oxide. Alternatively, for example, the insulator 325 may be added with a black pigment or dye. Furthermore, for example, a metal or the like may be embedded in the insulator 325. As described above, avalanche breakdown is induced in the depletion layer region extending from the semiconductor region 312 to the semiconductor region 311. At this time, even if avalanche light emission occurs, since the insulator 325 reflects or absorbs the light, a crosstalk, in which the pixel 101 (APD 201) adjacent to the pixel 101 (APD 201) where light emission occurs detects the light, can be suppressed. Adding metal oxide particles or embedding a metal in the insulator 325 rather than adding a colored material thereto can improve the sensitivity of the pixel 101 (APD 201) since light obliquely entering the pixel 101 is reflected by the insulator 325 (or the embedded metal).

The insulator 325 can be arranged, for example, from the main surface 391 of the semiconductor layer 301 to the height where the semiconductor region 312 is arranged. For example, the semiconductor layer 301 is etched from the side of the main surface 391 of the semiconductor layer 301 to form a trench to be the part 324a of the element isolation portion 324. Then, the insulator 325 is embedded in the trench. Furthermore, the semiconductor layer 301 is etched from the side of the main surface 392 of the semiconductor layer 301 to form a trench to be a part 324b of the element isolation portion 324, and the insulator 326 is embedded in the trench. Using these steps, the element isolation portion 324 can be formed. However, the present disclosure is not so limited, and the element isolation portion 324 may have any arrangement as long as the desired electric isolation between the pixels 101 (APDs 201) can be provided. For example, the insulator 325 and the insulator 326 may be formed using the same material, or may have the same arrangement. For example, in the arrangement shown in FIG. 6, the element isolation portion 324 is shown to be formed using an etching process including at least two stages. However, the present disclosure is not so limited, and a trench may be formed in the element isolation portion 324 by a single-stage etching process and the insulator 325 or the insulator 326 may be embedded therein.

In the arrangement shown in FIGS. 6-7B, a functional layer 321 including a pinning layer, a planarizing layer 322, and microlenses 323 are arranged on the main surface 392 of the semiconductor layer 301. Furthermore, the cured product 350 of the curable composition is arranged between the functional layer 321 and the planarizing layer 322. When the functional layer 321 including the pinning layer is arranged in contact with the main surface 392 of the semiconductor layer 301, holes are induced in the vicinity of the main surface 392 of the semiconductor layer 301, and a dark current is suppressed. For the functional layer 321 including the pinning layer, hafnium oxide, zirconium oxide, aluminum oxide, titanium oxide, tantalum oxide, or the like can be used. The functional layer 321 may have a single layer structure using one of these materials, or may have a layered structure using multiple materials. In other words, the functional layer 321 may have a layered structure and function as an anti-reflection layer. In this manner, the functional layer 321 can have a function of suppressing a dark current, an anti-reflection function, and the like.

The planarizing layer 322 arranged between the cured product 350 and the microlenses 323 is a layer for planarizing the surface on which the microlenses 323 are arranged. In a surface 352 of the cured product 350, trenches 351 are provided as shown in FIG. 6, and a material 353 is embedded therein. The planarizing layer 322 planarizes the unevenness that can be generated due to this arrangement. The planarizing layer 322 may be formed of an inorganic material or an organic material such as a resin. The planarizing layer 322 may have a layered structure obtained by stacking a plurality of material layers.

The microlens 323 can be formed using a resin material or the like. A color filter may be arranged between the functional layer 321 and the cured product 350, between the cured product 350 and the planarizing layer 322, or between the planarizing layer 322 and the microlens 323. Alternatively, the planarizing layer 322 may function as a color filter.

A plurality of trenches 351, each extending from the surface 352 of the cured product 350 toward the main surface 392 of the semiconductor layer 301, are provided in the cured product 350 of the curable composition. As shown in FIGS. 6 and 7B, the plurality of trenches 351 include a trench 351a (first trench) constituting a scattering diffraction structure arranged to at least partially overlap the APD 201 as the photoelectric conversion element 102, and a trench 351b (second trench) constituting an isolation structure arranged to overlap the element isolation portion 324. The trench 351 may be embedded with the material 353 having a refractive index different from the refractive index of the cured product 350. The material 353 embedded in the trench 351 may be fully embedded in the trench 351, or may have some voids. As the material 353 embedded in the trench 351, silicon oxide or silicon nitride may be used, an organic material such as a resin may be used, or a metal may be used. However, the present disclosure is not so limited, and the trench 351 provided in the cured product 350 of the curable composition may not be embedded with the material 353 (the trench 351 may be an air gap). The trench 351 can be formed to have, for example, a depth of about 20 nm to 200 nm from the surface 352 of the cured product 350 of the curable composition.

The trench 351a constituting the scattering diffraction structure is arranged to at least partially overlap the APD 201, and light entering the pixel 101 is scattered by the scattering diffraction structure. This causes the incident light to travel obliquely in the pixel 101, so that the optical path length larger than the thickness of the semiconductor layer 301 can be ensured, and the photoelectric conversion efficiency increases. Further, since the optical path length increases, it is possible to photoelectrically convert light of a longer wavelength than in a case where the scattering diffraction structure is not provided. In order to achieve sufficiently high diffraction of light having entered the pixel 101, the depth of the trench 351a constituting the scattering diffraction structure may be larger than the width of the trench 351a. For example, the depth of the trench 351a may be about 200 nm, and the width of the trench 351a may be about 100 nm to 150 nm. In addition, for example, the inner dimension of the rectangular unit structure of the trench 351a constituting the scattering diffraction structure (the interval between the trenches 351a adjacent to each other) as shown in FIG. 7B may be about 250 nm to 350 nm. FIG. 7B shows an example where square unit structures are periodically arranged as the scattering diffraction structure, but the present disclosure is not so limited. The unit structure may have a rectangular or diamond shape. The shape of the unit structure of the scattering diffraction structure is not limited to a rectangular shape, but may be an appropriate shape such as a triangle or a polygon with five or more sides.

The trench 351b constituting the isolation structure is arranged to overlap the element isolation portion 324, to suppress crosstalk in which light obliquely entering the pixel 101 enters the adjacent pixel 101 via the cured product 350 of the curable composition. As shown in FIG. 7B, the trench 351b may be arranged to surround each pixel 101. As shown in FIG. 7B, the trench 351a and the trench 351b may be arranged independently of each other (non-continuously).

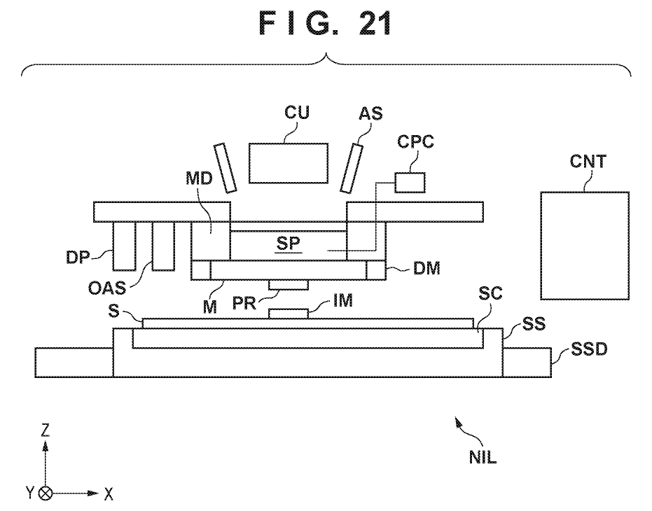

Next, a manufacturing method of the photoelectric conversion device 100 according to this embodiment will be described. Since the APDs and the like formed in the semiconductor layer 301 can be formed using a known semiconductor process, a description will be given here focusing on the trenches 351 formed in the cured product 350 of the curable composition. Before describing the specific manufacturing method, an imprint process used when forming the trenches 351 in the cured product 350 of the curable composition is described. FIG. 21 schematically shows an example of the arrangement of an imprint apparatus NIL. The imprint apparatus NIL is an apparatus that transfers the pattern of a mold M to a curable composition IM on a substrate S. As the curable composition IM, a composition (also referred to as a resin in an uncured state) to be cured by receiving curing energy is used. As the curing energy, an electromagnetic wave, heat, or the like is used. The electromagnetic wave is light selected from the wavelength range of 10 nm (inclusive) to 1 mm (inclusive), for example, infrared light, a visible light beam, ultraviolet light, or the like. The curable composition IM may be understood as a composition cured by light irradiation or a composition cured by heating. Among these, a photo-curable composition cured by light contains at least a polymerizable compound and a photopolymerization initiator, and may contain a nonpolymerizable compound or a solvent, as needed. The nonpolymerizable compound can be at least one material selected from the group consisting of a sensitizer, a hydrogen donor, an internal mold release agent, a surfactant, an antioxidant, and a polymer component. The curable composition IM can be applied onto the substrate in a film shape by a spin coater or a slit coater. The curable composition IM may be applied onto the substrate in a droplet shape or in an island or film shape formed by connecting a plurality of droplets using a liquid injection head. The viscosity (the viscosity at 25° C.) of the curable composition IM is, for example, 1 mPa∙s (inclusive) to 100 mPa∙s (inclusive).

The imprint apparatus NIL can include a substrate stage SS including a substrate chuck SC that holds the substrate S, and a substrate driving mechanism SSD that drives the substrate stage SS. The imprint apparatus NIL can also include a mold driving mechanism MD that holds and drives the mold M. The substrate driving mechanism SSD and the mold driving mechanism MD constitute a relative driving mechanism that drives at least one of the substrate S and the mold M to adjust the relative position between the substrate S and the mold M. Adjustment of the relative position by the relative driving mechanism includes driving for bringing the mold M into contact with the curable composition IM on the substrate S and driving for separating the mold M from the cured product of the curable composition IM. Adjustment of the relative position by the relative driving mechanism also includes alignment between the substrate S (a shot region thereof) and the mold M (a pattern region PR thereof). The substrate driving mechanism SSD can be configured to drive the substrate S with respect to a plurality of axes (for example, three axes including the X-axis, Y-axis, and θZ-axis, or six axes including the X-axis, Y-axis, Z-axis, θX-axis, θY-axis, and θZ-axis). The imprint apparatus NIL can include a mold deformation mechanism DM that deforms the two-dimensional shape of the pattern region PR of the mold M. The mold deformation mechanism DM can deform the pattern region PR of the mold M by, for example, applying a force to the side surface of the mold M. The mold driving mechanism MD can be configured to drive the mold M with respect to a plurality of axes (for example, three axes including the Z-axis, θX-axis, and θY-axis, or six axes including the X-axis, Y-axis, Z-axis, θX-axis, θY-axis, and θZ-axis). The imprint apparatus NIL can include a pressure controller CPC that controls the three-dimensional shape of the pattern region PR of the mold M by adjusting the pressure in a sealed space SP formed on the back surface of the mold M. It is possible to deform the pattern region PR of the mold M into a downward convex shape or planarize it by adjusting the pressure in the sealed space SP by the pressure controller CPC.

The imprint apparatus NIL can include one or a plurality of alignment scopes AS for measuring the alignment error between the shot region of the substrate S and the pattern region PR of the mold M. The imprint apparatus NIL can include a curing unit CU that forms a cured film (cured product) by curing the curable composition IM by applying curing energy to the curable composition IM via the mold M. The imprint apparatus NIL can include a dispenser DP that applies or arranges the curable composition IM onto the substrate S. The imprint apparatus NIL can include an off-axis scope OAS for detecting the position of the alignment mark of the substrate S. The imprint apparatus NIL can include a control unit CNT that controls the respective components of the imprint apparatus NIL. The control unit CNT is an information processing apparatus that can be formed from, for example, a Programmable Logic Device (PLD) such as a Field Programmable Gate Array (FPGA), an Application Specific Integrated Circuit (ASIC), a computer incorporating a program, or a combination of some or all of these.

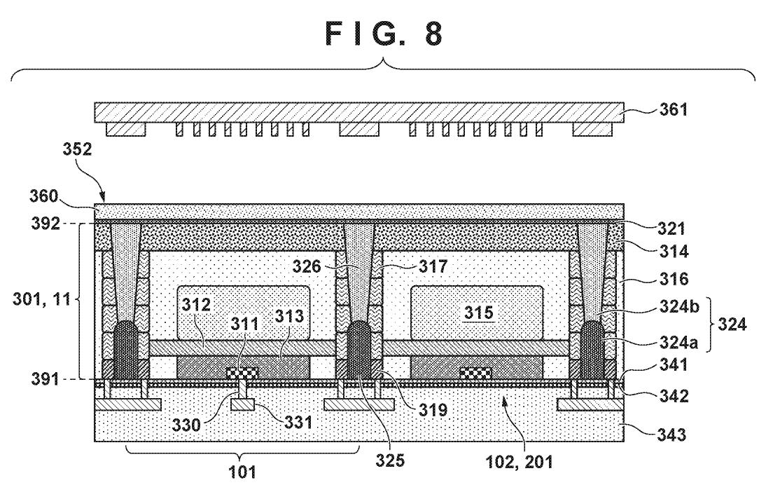

A method of forming the trenches 351 in the cured product 350 of the curable composition by using an imprint process will be described below. First, the semiconductor layer 301 where the APDs 201 and the like are formed is prepared as shown in FIG. 8. Then, in the imprint apparatus NIL, a step of arranging a curable composition 360 (the curable composition IM in FIG. 21) by the dispenser DP so as to cover the main surface 392 of the semiconductor layer 301 (or the functional layer 321, if arranged) is executed. A mold 361 (the mold M in FIG. 21) is also prepared.

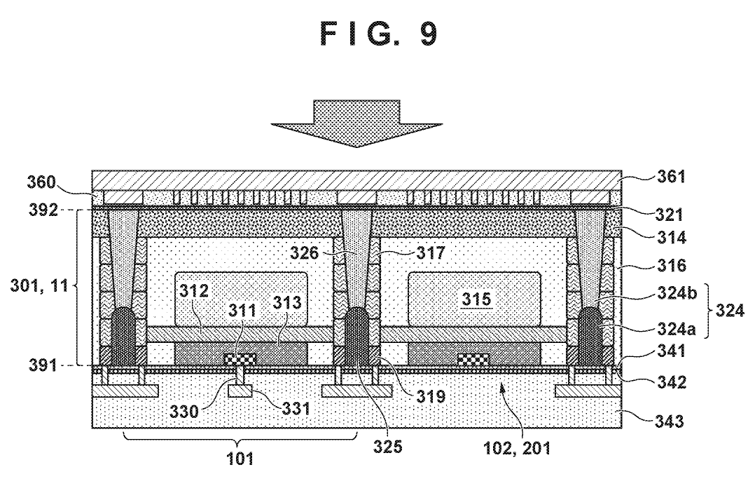

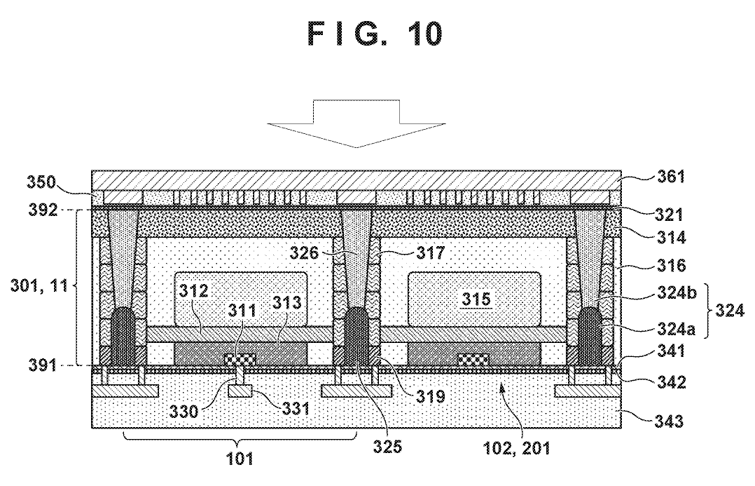

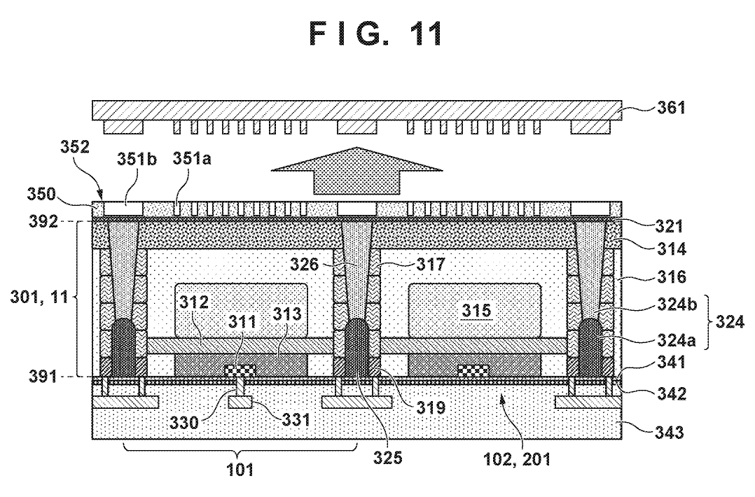

After the curable composition 360 is arranged, as shown in FIG. 9, a step of bringing the mold 361 into contact with the curable composition 360 is executed. Then, as shown in FIG. 10, in a state in which the curable composition 360 and the mold 361 are in contact with each other, a step of curing the curable composition 360 by the curing unit CU is executed. With this step, the cured product 350 of the curable composition 360 is formed. After the cured product 350 is formed, as shown in FIG. 11, a step of separating the mold 361 from the cured product 350 is executed. A process including the step of arranging the curable composition 360 on the semiconductor layer 301, the step of bringing the mold 361 into contact with the curable composition 360, the step of curing the curable composition 360, and the step of separating the mold 361 from the cured product 350 of the curable composition 360 can be called an imprint process. In this manner, in this embodiment, using the imprint process, the cured product 350 provided with the trenches 351 is arranged on the semiconductor layer 301.

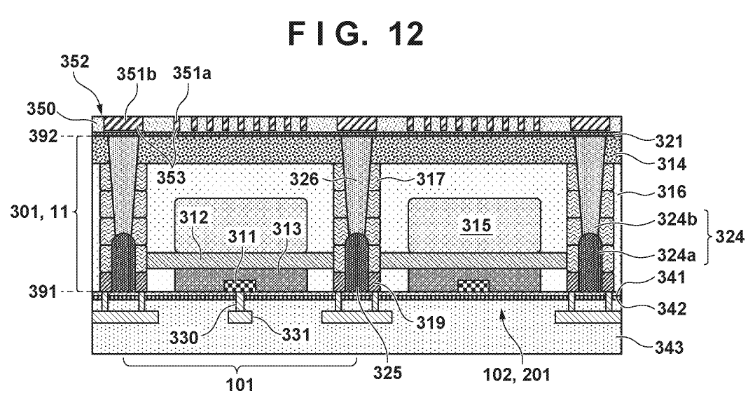

After the cured product 350 provided with the trenches 351 is formed, as shown in FIG. 12, the material 353 is embedded in the trenches 351. The material 353 embedded in the trenches 351 may be formed using an appropriate method such as a chemical vapor deposition (CVD) method, a sputtering method, or a spin-on-glass (SOG) method in accordance with the material 353 to be used. On the other hand, for the cured product 350 (curable composition 360), an acrylic resin, a phenolic resin, or the like can be used. Accordingly, the material 353 can be embedded in the trenches 351 using a relatively low temperature process. For example, the material 353 may be formed by forming a material film including silicon oxide or the like to cover the surface 352 of the cured product 350 using the CVD method or the SOG method, and removing the unnecessary portion using an etch back method or a polishing method. After the material 353 is embedded in the trenches 351, the planarizing layer 322 is formed to cover the cured product 350, and the microlenses 323 are further formed to respectively overlap the photoelectric conversion elements 102 (APDs 201). Here, an example is shown where the planarizing layer 322 is formed after the material 353 is embedded in the trench 351. However, the present disclosure is not so limited, and the material 353 embedded in the trenches 351 may be formed integrally with at least a part of the planarizing layer 322. For example, a material film may be formed to cover the surface 352 of the cured product 350 using the CVD method or the SOG method, and its surface may be polished, thereby forming the planarizing layer 322 together with the material 353 embedded in the trenches 351. Alternatively, the material 353 embedded in the trenches 351 and a part of the planarizing layer 322 may be formed by these steps, and a film formation process may be further performed to form the planarizing layer 322. By including these steps, the photoelectric conversion device 100 as shown in FIG. 6 can be manufactured.

When implementing the scattering diffraction structure by forming the trenches in the semiconductor layer 301, the etching process for forming the trenches in the semiconductor layer 301 causes plasma damage. Due to this, dark current noise increases, and the characteristics of the photoelectric conversion device can be degraded. In addition, for example, since an additional process for suppressing plasma damage is required, the manufacturing steps increase. This can lead to an increase in cost. On the other hand, in this embodiment, the trench 351a functioning as the scattering diffraction structure is provided in the cured product 350 of the curable composition arranged on the semiconductor layer 301. With this, the scattering diffraction structure can be formed on the semiconductor element 102 (APD 201) without causing plasma damage and the like in the semiconductor layer 301. As a result, improvement of the characteristics of the photoelectric conversion device 100 is simplifier than in a case where the trenches are formed in the semiconductor layer 301.

The scattering diffraction structure diffracts light by the difference between the refractive index of the cured product 350 and the refractive index of the material 353 embedded in the trench 351a. Therefore, the cured product 350 and the material 353 embedded in the trench 351 need to have different refractive indices. For example, the cured product 350 may have a higher refractive index than the material 353 embedded in the trench 351. When a silicon oxide-based material (for example, the refractive index of silicon oxide is about 1.46) is used as the material 353 to be embedded in the trench 351a, the cured product 350 may have a refractive index of, for example, about 1.5 to 2.0. The cured product 350 may be added with metal oxide particles to improve the refractive index. For example, the cured product 350 may be an acrylic resin or a phenolic resin added with titanium oxide (titania), zirconium oxide (zirconia), or the like. The cured product 350 may be a photo-curable composition or a thermosetting composition. Alternatively, the cured product 350 may have a lower refractive index than the material 353 embedded in the trench 351. In this case, the trench 351a provided in the cured product 350 may be embedded with a dielectric such as aluminum oxide, lanthanum oxide, or silicon nitride as the material 353. For example, regardless of the refractive index of the cured product 350, a metal such as aluminum may be embedded as the material 353 in the trench 351a provided in the cured product 350.

In a case of using the above-described imprint process, in the step of bringing the mold 361 into contact with the curable composition 360 shown in FIG. 9, the curable composition 360 exists between the protruding portions of the mold 361 and the semiconductor layer 301 (functional layer 321). Accordingly, as shown in FIG. 6, a part of the cured product 350 is arranged between the bottom surfaces of the trenches 351 and the main surface 392 of the semiconductor layer 301 (or the functional layer 321, if arranged). For example, the thickness and refractive index of each of respective layers such as the material 353 embedded in the trench 351, the cured product 350 between the bottom surface of the trench 351a and the functional layer 321, and the functional layer 321 are adjusted to appropriate values. With this, each layer may function as an anti-reflection layer or the like.

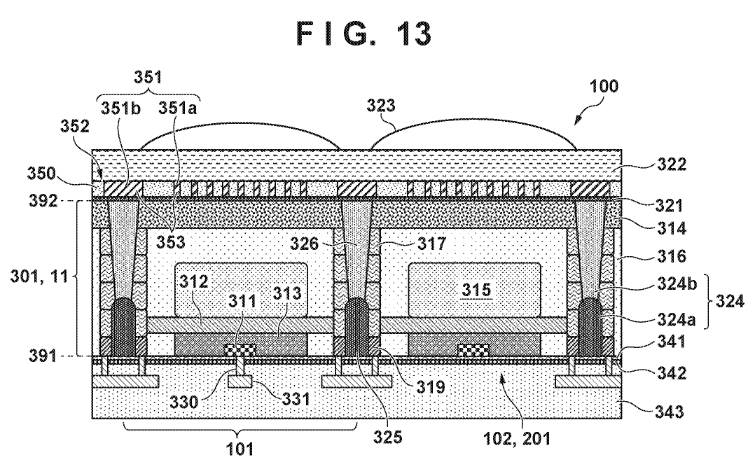

Alternatively, for example, as shown in FIG. 13, the trenches 351 may reach the functional layer 321. After the trenches 351 are formed using the imprint process and before the trenches 351 are embedded with the material 353, an additional etching process is executed. Thus, the arrangement as shown in FIG. 13 can be implemented. In this etching process, the functional layer 321 may function as an etching stop layer. In the photoelectric conversion device 100 arranged with the plurality of pixels 101, this can suppress variation of the depth of the trench 351 for each pixel 101.

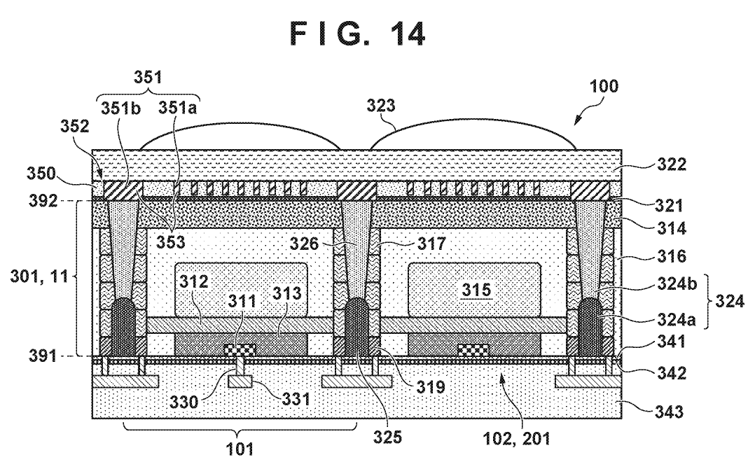

Alternatively, for example, as shown in FIG. 14, the trench 351b may reach the element isolation portion 324. This can further suppress the crosstalk between the pixels 101. For example, the trench 351b may be formed by, after the trenches 351 are formed, arranging a resist pattern to cover the trench 351a and further etching the trench 351b. Alternatively, for example, in the mold 361, the portion for forming the trench 351b is made protruding from the portion for forming the trench 351a. Accordingly, the trenches 351 are formed in the cured product 350 such that the depth of the trench 351b is larger than the depth of the trench 351a. Thereafter, the trench 351b may be formed to reach the element isolation portion 324 by executing an additional etching process before embedding the trenches 351 with the material 353.

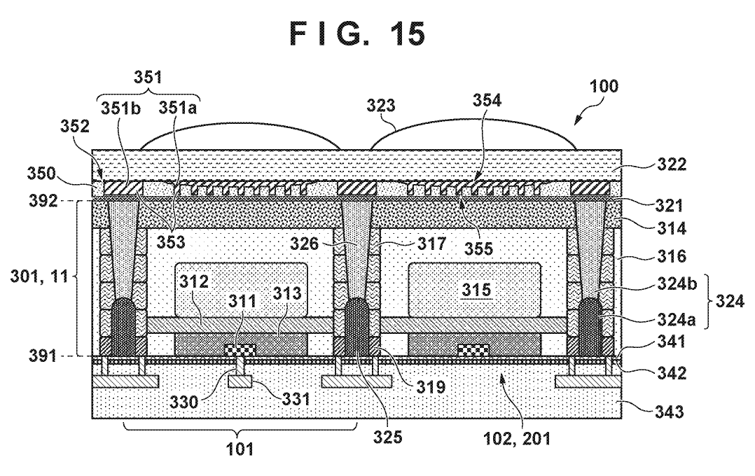

Furthermore, for example, as shown in FIG. 15, the surface 352 of the cured product 350 may include a recessed portion 354 that is recessed in a curved surface shape toward the main surface 392 of the semiconductor layer 301, and the trench 351a constituting the scattering diffraction structure may be arranged in the recessed portion 354. It can also be said that the scattering diffraction structure includes the recessed portion 354 that is provided in the surface 352 of the cured product 350 and recessed in a curved surface shape toward the main surface 392 of the semiconductor layer 301, and a grid portion 355 constituted by the trench 351a extending from the recessed portion 354 toward the main surface 392 of the semiconductor layer 301. If the refractive index of the cured product 350 is higher than the refractive index of the material 353 embedded in the trench 351, the recessed portion 354 functions as a concave lens. With this, more components of light having entered the pixel 101 travel toward the element isolation portion 324 and are reflected by the surface of the element isolation portion 324. As a result, a larger optical path length than in a case without the recessed portion 354 can be ensured. The positions of the bottom surfaces of the trench 351a and the trench 351b can be the positions described above.

Application examples of the photoelectric conversion device 100 in which the above-described pixels 101 are arranged will be described below.

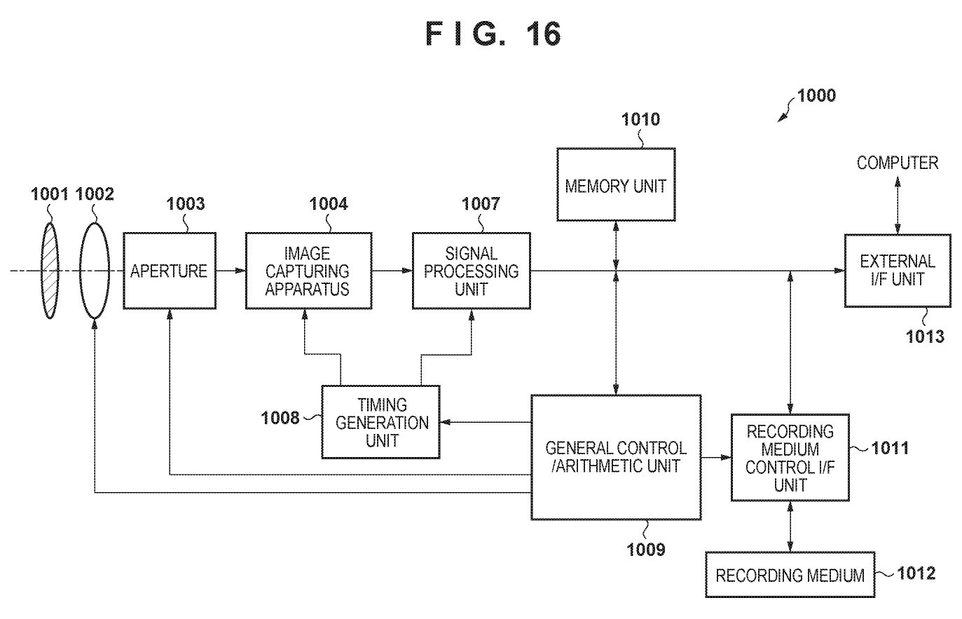

FIG. 16 is a block diagram showing the schematic arrangement of a photoelectric conversion system. The photoelectric conversion device 100 described above is applicable to various kinds of photoelectric conversion systems. Examples of photoelectric conversion systems to which the photoelectric conversion device is applicable are a digital still camera, a digital camcorder, a monitoring camera, a copying machine, a facsimile apparatus, a mobile phone, an in-vehicle camera, and an observation satellite. A camera module including an optical system such as a lens and an image capturing device is also included in the photoelectric conversion systems. FIG. 16 exemplarily shows the block diagram of a digital still camera as an example thereof.

A photoelectric conversion system 1000 exemplarily shown in FIG. 16 includes an image capturing device 1004 as an example of the photoelectric conversion device, a lens 1002 that forms an optical image of an object on the image capturing device 1004, an aperture 1003 configured to change the amount of light passing through the lens 1002, and a barrier 1001 configured to protect the lens 1002. The lens 1002 and the aperture 1003 form an optical system (optical device) that condenses light to the image capturing device 1004. The image capturing device 1004 is the photoelectric conversion device 100 (image capturing device) described above, and converts the optical image formed by the lens 1002 into an electrical signal.

The photoelectric conversion system 1000 also includes a signal processing unit 1007 that is an image generation unit configured to generate an image by processing an output signal output from the image capturing device 1004. The signal processing unit 1007 functions as a processing device that performs an operation of performing various kinds of correction and compression as needed, thereby outputting image data. The signal processing unit 1007 may be formed on a semiconductor substrate on which the image capturing device 1004 is provided or may be formed on a semiconductor substrate different from the image capturing device 1004. In addition, the image capturing device 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control interface unit (recording medium control I/F unit) 1011 configured to perform record or readout for the recording medium 1012. The recording medium control I/F unit 1011 and the recording medium 1012 can form a part of a storage device. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1008 that outputs various kinds of timing signals to the image capturing device 1004 and the signal processing unit 1007. The general control/arithmetic unit 1009 and the timing generation unit 1008 can form a part of a control device configured to control an operation of the photoelectric conversion system 1000. In this example, the timing signal and the like may be externally input, and the photoelectric conversion system 1000 need only include at least the image capturing device 1004, and the signal processing unit 1007 that processes an output signal output from the image capturing device 1004.

The image capturing device 1004 outputs an image capturing signal to the signal processing unit 1007. The signal processing unit 1007 executes predetermined signal processing for the image capturing signal output from the image capturing device 1004, and outputs image data. The signal processing unit 1007 generates an image using the image capturing signal. A display device such as a display for displaying the generated image may be arranged in the photoelectric conversion system 1000. As described above, according to this embodiment, it is possible to implement the photoelectric conversion system 1000 to which the photoelectric conversion device 100 (image capturing device) described above is applied.

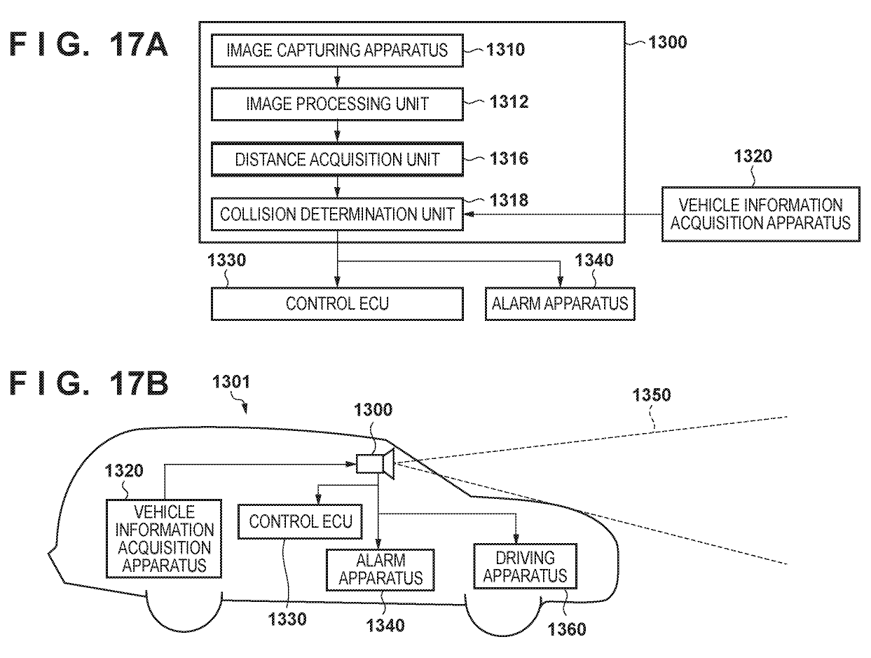

FIGS. 17A and 17B are views showing the arrangements of a photoelectric conversion system 1300 and a moving body 1301, respectively. FIG. 17A shows an example of a photoelectric conversion system concerning an in-vehicle camera. The photoelectric conversion system 1300 includes an image capturing device 1310. The image capturing device 1310 is the photoelectric conversion device 100 (image capturing device) described above. The photoelectric conversion system 1300 includes an image processing unit 1312 that performs image processing for a plurality of image data acquired by the image capturing device 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using a ToF method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by an FPGA, an ASIC, or the like, or may be implemented by a combination of these.

The photoelectric conversion system 1300 is connected to a vehicle information acquisition device 1320, and can acquire vehicle information such as a vehicle speed, a yaw rate, and a steering angle. The photoelectric conversion system 1300 is also connected to an Electronic Control Unit (ECU) 1330 that is a control device (control unit) configured to output a control signal for generating a braking force to the vehicle based on the determination result of the collision determination unit 1318. Furthermore, the photoelectric conversion system 1300 is connected to an alarm device 1340 that generates an alarm to the driver based on the determination result of the collision determination unit 1318. For example, if collision possibility is high as the determination result of the collision determination unit 1318, the ECU 1330 controls a driving device (mechanical device) 1360 to perform braking, releasing an accelerator pedal, or suppressing engine output, thereby controlling the vehicle for avoiding collision and reducing damage. The alarm device 1340 sounds an alarm, displays alarm information on the screen of a car navigation system or the like, or applies a vibration to the seat belt or a steering wheel, thereby making an alarm to the user.

In this embodiment, the periphery of the vehicle (moving body 1301), for example, the front or rear side is captured by the photoelectric conversion system 1300. FIG. 17B shows the photoelectric conversion system when capturing the front side (image capturing range 1350) of the vehicle. The vehicle information acquisition device 1320 sends an instruction to the photoelectric conversion system 1300 or the image capturing device 1310. With this configuration, it is possible to further improve the accuracy of distance measurement.

The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving device) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller, or the like. In addition, the photoelectric conversion system can be applied not only to a moving body but also to an apparatus that broadly uses object recognition, such as an intelligent transport system (ITS).

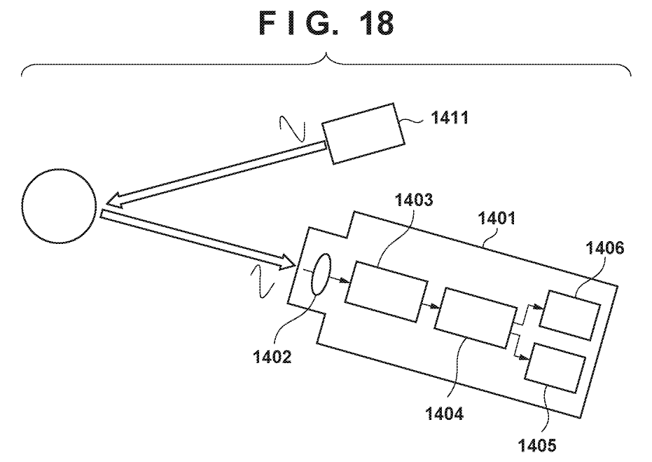

FIG. 18 is a block diagram showing an example of the arrangement of a distance image sensor 1401 as the photoelectric conversion system. As shown in FIG. 18, the distance image sensor 1401 includes an optical system 1402, a photoelectric conversion device 1403, an image processing circuit 1404, a monitor 1405, and a memory 1406. Then, the distance image sensor 1401 can receive light (modulated light or pulsed light) projected from a light source device 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion device 1403 and forms an image on the light-receiving surface (sensor portion) of the photoelectric conversion device 1403.

As the photoelectric conversion device 1403, the photoelectric conversion device 100 described above is applied, and a distance signal indicating a distance obtained from a light reception signal output from the photoelectric conversion device 1403 is supplied to the image processing circuit 1404.

The image processing circuit 1404 performs image processing of creating a distance image based on the distance signal supplied from the photoelectric conversion device 1403. Then, the distance image (image data) obtained by the image processing is supplied to and displayed on the monitor 1405, and supplied to and stored (recorded) in the memory 1406.

The distance image sensor 1401 having such arrangement can acquire, for example, a more accurate distance image along with improvement in characteristic of pixels by applying the above-described photoelectric conversion device 100.

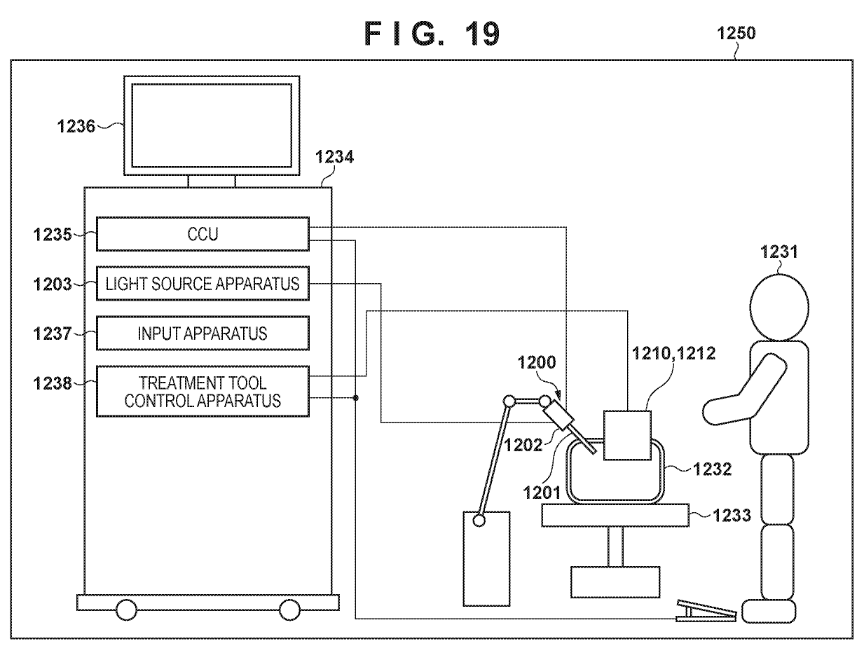

FIG. 19 is a view showing an example of the schematic arrangement of an endoscopic surgery system 1250 as the photoelectric conversion system. FIG. 19 shows a state in which an operator (doctor) 1231 operates on a patient 1232 on a patient bed 1233 using the endoscopic surgery system 1250. As shown in FIG. 19, the endoscopic surgery system 1250 is formed from an endoscope 1200, a surgical tool 1210, and a cart 1234 on which various devices for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 19, the endoscope 1200 formed as a hard mirror including a hard lens barrel 1201 is shown. However, the endoscope 1200 may be formed as a soft mirror, including a soft lens barrel.

An opening in which an objective lens is fitted is provided at the distal end of the lens barrel 1201. A light source device 1203 is connected to the endoscope 1200, and light generated by the light source device 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion device are provided in the camera head 1202, and reflected light (observation light) from the observation target is condensed by the optical system to the photoelectric conversion device. The observation light is photoelectrically converted by the photoelectric conversion device to generate an electrical signal corresponding to the observation light, that is, an image signal corresponding to an observation image. As the photoelectric conversion device, the photoelectric conversion device 100 (image capturing device) described above can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display device 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display device 1236 displays the image based on the image signal having undergone the image processing by the CCU 1235.

The light source device 1203 is formed from a light source such as a Light Emitting Diode (LED), and supplies, to the endoscope 1200, irradiation light at the time of imaging an operation portion or the like.

An input device 1237 is an input interface to the endoscopic surgery system 1250. The user can input various kinds of information or instructions to the endoscopic surgery system 1250 via the input device 1237.

A treatment tool control device 1238 controls driving of an energy treatment tool 1212 for ablation or incision of the tissue, sealing of a blood vessel, or the like.

The light source device 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source device 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source device 1203 may be controlled to change the intensity of light to be output at predetermined time intervals. It is possible to time-divisionally acquire images by controlling driving of the image sensor of the camera head 1202 in synchronism with the timing of changing the intensity of the light, and combine the images, thereby generating an image of a high dynamic range without shadow detail loss or highlight detail loss.

The light source device 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing irradiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source device 1203 can be configured to supply narrow band light and/or excitation light corresponding to such special light observation.

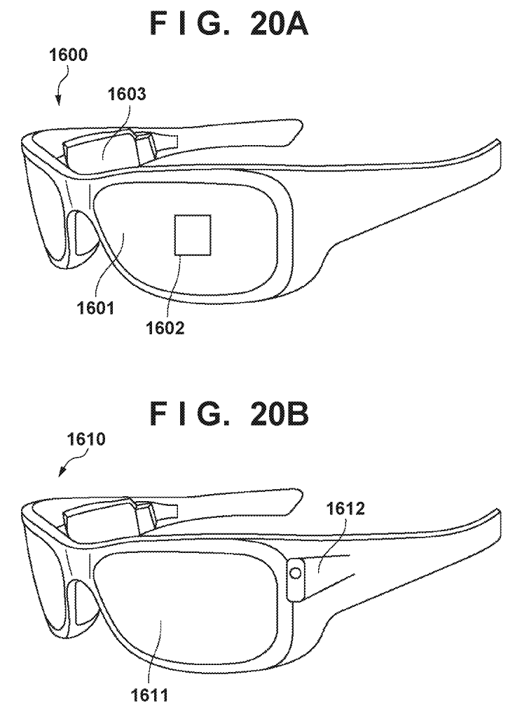

FIGS. 20A and 20B describe glasses 1600 and 1610 (smartglasses) as the photoelectric conversion systems, respectively. The glasses 1600 shown in FIG. 20A include a photoelectric conversion device 1602. The photoelectric conversion device 1602 is the photoelectric conversion device 100 (image capturing device) described above. A display device including the light emitting device such as an OLED or LED may be provided on the back surface side of a lens 1601. One or a plurality of photoelectric conversion devices 1602 may be provided. Alternatively, a plurality of kinds of photoelectric conversion devices may be used in combination. The arrangement position of the photoelectric conversion device 1602 is not limited to that shown in FIG. 20A.

The glasses 1600 further include a control device 1603. The control device 1603 functions as a power supply that supplies electric power to the photoelectric conversion device 1602 and the above-described display device. In addition, the control device 1603 controls the operations of the photoelectric conversion device 1602 and the display device. An optical system configured to condense light to the photoelectric conversion device 1602 is formed on the lens 1601.

FIG. 20B describes glasses 1610 (smartglasses) according to one application example. The glasses 1610 include a control device 1612, and a photoelectric conversion device corresponding to the photoelectric conversion device 1602 and a display device are mounted on the control device 1612. The photoelectric conversion device in the control device 1612 and an optical system configured to project light emitted from the display device are arranged in a lens 1611, and an image is projected to the lens 1611. The control device 1612 functions as a power supply that supplies electric power to the photoelectric conversion device and the display device, and controls the operations of the photoelectric conversion device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment can include a photoelectric conversion device including a light receiving element, and control a displayed image of the display device based on the line-of-sight information of the user from the photoelectric conversion device.

More specifically, the display device decides a first visual field region at which the user is gazing and a second visual field region other than the first visual field region based on the line-of-sight information. The first visual field region and the second visual field region may be decided by the control device of the display device, or those decided by an external control device may be received. In the display region of the display device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control device of the display device, or those decided by an external control device may be received. The resolution of the region of higher priority may be controlled to be higher than the resolution of the region other than the region of higher priority. That is, the resolution of the region of relatively low priority may be low.

Artificial Intelligence (AI) may be used to decide the first visual field region or the region of higher priority. The AI may be a model configured to estimate the angle of the line of sight and the distance to a target object ahead in the line of sight from the image of the eyeball using the image of the eyeball and the direction of actual viewing of the eyeball in the image as supervised data. The AI program may be held by the display device, the photoelectric conversion device, or an external device. If the external device holds the AI program, it is transmitted to the display device via communication.

If display control is performed based on line-of-sight detection, this can be applied to smartglasses further including a photoelectric conversion device configured to capture the image of the outside. The smartglasses can display the captured outside image information in real time.

According to the present disclosure, a technique advantageous in improving the characteristics of a photoelectric conversion device can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-205698, filed Nov. 26, 2024, which is hereby incorporated by reference herein in its entirety.

What is claimed is:

1. A photoelectric conversion device comprising:
a semiconductor layer having a first surface, a first photoelectric conversion element, and a second photoelectric conversion element adjacent to each other; and
an isolation portion arranged to electrically isolate the first photoelectric conversion element from the second photoelectric conversion element, wherein:
the first surface is configured for a cured product to be arranged thereon,
a plurality of trenches extending from a surface of the cured product toward the first surface are provided in the cured product,
a first trench of the plurality of trenches forms a scattering diffraction structure arranged to overlap the first photoelectric conversion element, and
a second trench of the plurality of trenches forms an isolation structure arranged to overlap the isolation portion.

2. The photoelectric conversion device according to claim 1, further comprising:
a functional layer arranged between the first surface and the cured product; and
a planarizing layer arranged to cover the cured product,
wherein the plurality of trenches extend between the functional layer and the planarizing layer.

3. The photoelectric conversion device according to claim 1, where the cured product is a curable composition.

4. The photoelectric conversion device according to claim 1, further comprising:
a planarizing layer,
wherein the second trench extends between the isolation portion and the planarizing layer.

5. The photoelectric conversion device according to claim 1, wherein
a part of the cured product is arranged between bottom surfaces of the plurality of trenches and the first surface.

6. The photoelectric conversion device according to claim 1, wherein
the surface of the cured product includes a recessed portion having a curved shape that is recessed toward the first surface, and
the first trench is arranged in the recessed portion.

7. The photoelectric conversion device according to claim 6, wherein
the plurality of trenches and the recessed portion are embedded with a material having a refractive index different from a refractive index of the cured product.

8. The photoelectric conversion device according to claim 1, wherein
the plurality of trenches are embedded with a material having a refractive index different from a refractive index of the cured product.

9. The photoelectric conversion device according to claim 7, wherein
the refractive index of the cured product is higher than the refractive index of the material.

10. The photoelectric conversion device according to claim 7, further comprising:
a planarizing layer is arranged to cover the cured product,
wherein the material embedded in the plurality of trenches is formed integrally with at least a part of the planarizing layer.

11. The photoelectric conversion device according to claim 1, further comprising:
a planarizing layer arranged to cover the cured product; and
a microlens arranged on the planarizing layer to overlap the first photoelectric conversion element.

12. The photoelectric conversion device according to claim 1, wherein
the cured product includes metal oxide particles.

13. The photoelectric conversion device according to claim 1, wherein
each of the first photoelectric conversion element and the second photoelectric conversion element is an avalanche photodiode.

14. The photoelectric conversion device according to claim 1, further comprising:
a second surface;
an other semiconductor layer arranged to face the second surface; and
an element configured to operate the first photoelectric conversion element and the second photoelectric conversion element, wherein the element is arranged in the other semiconductor layer.

15. A photoelectric conversion device comprising:
a semiconductor layer having a surface;
a photoelectric conversion element;
a cured product arranged on the surface;
a scattering diffraction structure provided in the cured product to overlap the photoelectric conversion element;
a recessed portion provided in a surface of the cured product and recessed in a curved surface shape toward the surface; and
a grid portion formed by a trench extending from the recessed portion toward the surface.

16. The photoelectric conversion device of claim 15, wherein the cured product is a curable composition.

17. A photoelectric conversion system comprising:
the photoelectric conversion device according to claim 1; and
a signal processing unit configured to generate an image using a signal output from the photoelectric conversion device.

18. A moving body comprising:
the photoelectric conversion device according to claim 1; and
a controller configured to control movement of the moving body using a signal output from the photoelectric conversion device.

19. An apparatus comprising:
the photoelectric conversion device according to claim 1, wherein the photoelectric conversion device is configured to output at least one signal to at least one of:
an optical device;
a control device;
a processing device configured to process the signal output from the photoelectric conversion device;
a display device configured to display information obtained by the photoelectric conversion device;
a storage device configured to store information obtained by the photoelectric conversion device; and
a mechanical device configured to operate based on information obtained by the photoelectric conversion device.

20. A method of manufacturing a photoelectric conversion device that includes: a semiconductor layer having a surface, a first photoelectric conversion element, and a second photoelectric conversion element adjacent to each other; an isolation portion arranged to electrically isolate the first photoelectric conversion element from the second photoelectric conversion element; a scattering diffraction structure arranged on the surface to overlap the first photoelectric conversion element; and an isolation structure arranged on the surface to overlap the isolation portion, the method comprising:
forming, using an imprint process, a trench constituting the scattering diffraction structure and a trench constituting the isolation structure which are formed of a cured product of a curable composition on the surface.
